(19) United States
(12) Patent Application Publication
(10) Pub. No.: US 2014/0290703 A1
(43) Pub. Date: Oct. 2, 2014

(54) SUBSTRATE PROCESSING APPARATUS AND SUBSTRATE PROCESSING METHOD

(71) Applicant: DAINIPPON SCREEN MFG. CO., LTD., KYOTO (JP)

(72) Inventors: Kenji KOBAYASHI, Kyoto (JP); Kenji IZUMOTO, Kyoto (JP); Akihisa IWASAKI, Kyoto (JP); Takemitsu MIURA, Kyoto (JP); Kazuhide SAITO, Kyoto (JP)

(73) Assignee: DAINIPPON SCREEN MFG. CO., LTD., KYOTO (JP)

(21) Appl. No.: 14/225,689

(22) Filed: Mar. 26, 2014

(30) Foreign Application Priority Data
Mar. 28, 2013 (JP) P2013-069990

(51) Int. Cl. H01L 21/67; H01L 21/02

(52) U.S. Cl. CPC H01L 21/67051; H01L 21/02052
USPC 134/33; 134/157

(57) ABSTRACT

A substrate processing apparatus includes a substrate supporting part for supporting a substrate in a horizontal state, an upper nozzle for discharging deionized water as a cleaning solution toward a center portion of an upper surface of the substrate, and a substrate rotating mechanism for rotating the substrate supporting part together with the substrate around a central axis directed in a vertical direction. In the substrate processing apparatus, the plurality of discharge ports are provided in the upper nozzle, and the flow rate of the deionized water to be supplied onto the center portion of the substrate from the upper nozzle can be ensured, with the flow rate of the deionized water from each discharge port reduced. It is thereby possible to perform appropriate cleaning of the upper surface of the substrate while suppressing electrification at the center portion of the substrate.

### TECHNICAL FIELD

The present invention relates to a technique for processing a substrate.

### BACKGROUND ART

In a process of manufacturing a semiconductor substrate (hereinafter, referred to simply as a “substrate”), conventionally, various processings are performed on a substrate by using many types of substrate processing apparatuses. By supplying a chemical liquid onto a substrate having a surface on which a resist pattern is formed, for example, a processing such as etching or the like is performed on the surface of the substrate. Further, after etching or the like is finished, a process of removing the resist from the substrate and/or cleaning the substrate is also performed.

Japanese Patent Application Laid-Open No. 2004-158588, for example, discloses a substrate processing apparatus capable of removing organic substances deposited on a substrate by using a removal liquid. In the substrate processing apparatus, cleaning of the substrate is performed by supplying deionized water from a deionized water nozzle onto the substrate being rotated.

In the cleaning of a substrate by using deionized water, it is known that contact between the substrate having a surface on which an insulating film is formed and the deionized water having high electrical resistivity, or the like, causes the substrate to be electrically charged (electrified). When the amount of electrostatic charges on the substrate increases, there is a possibility that redeposition of particles during or after the cleaning, damage of wires due to electric discharge, or the like may occur.

As a method of suppressing electrification of a substrate, known is a method of cleaning the substrate by using carbon dioxide dissolved water in which carbon dioxide is dissolved in deionized water to reduce the electrical resistivity. In a case where copper wiring is formed on the substrate, however, in the cleaning using the carbon dioxide dissolved water, there is a possibility that the copper wire may be corroded by the carbon dioxide dissolved water. Further, as compared with the cleaning using the deionized water, the cost for the cleaning increases.

### SUMMARY OF INVENTION

The present invention is intended for a substrate processing apparatus for processing a substrate, and it is an object of the present invention to suppress electrification of a substrate while appropriately cleaning the substrate.

The substrate processing apparatus according to the present invention includes a substrate supporting part for supporting a substrate in a horizontal state, a nozzle for discharging deionized water as a cleaning solution toward a center portion of an upper surface of the substrate from a plurality of discharge ports, and a substrate rotating mechanism for rotating the substrate supporting part together with the substrate around a central axis directed in a vertical direction. By the present invention, it is possible to suppress electrification of a substrate while appropriately cleaning the substrate.

In one preferred embodiment of the present invention, the plurality of discharge ports include a central discharge port disposed at a center and a plurality of peripheral discharge ports disposed at regular angular intervals on a circumference around the central axis.

In another preferred embodiment of the present invention, the plurality of discharge ports are disposed within a circle having a radius smaller than or equal to 60 mm around the central axis.

In still another preferred embodiment of the present invention, the plurality of discharge ports are disposed within a circle having a radius smaller than or equal to 40% of a radius of the substrate around the central axis.

In yet another preferred embodiment of the present invention, a flow rate of the cleaning solution discharged from each of the plurality of discharge ports is lower than or equal to 1 liter per minute.

In further preferred embodiment of the present invention, an angle formed by a discharge direction of the cleaning solution from at least one discharge port among the plurality of discharge ports and the central axis is larger than or equal to 30 degrees.

In still another preferred embodiment of the present invention, the substrate processing apparatus further includes a sealed space forming part forming an internal space which is sealed, in which a cleaning process is performed on the substrate by using the cleaning solution.

In another preferred embodiment of the present invention, the cleaning solution is continuously discharged like a liquid column from each of the plurality of discharge ports.

The present invention is also intended for a substrate processing method of processing a substrate. The substrate processing method according to the present invention includes a) rotating a substrate in a horizontal state around a central axis directed in a vertical direction, and b) discharging deionized water as a cleaning solution toward a center portion of an upper surface of the substrate from a plurality of discharge ports.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a cross-sectional view showing a substrate processing apparatus in accordance with one preferred embodiment;

FIG. 2 is a bottom view of an upper nozzle;

FIG. 3 is a block diagram showing a gas-liquid supply part and a gas-liquid exhaust part;

FIG. 4 is a flowchart showing an operation flow of the substrate processing apparatus;

FIGS. 5 and 6 are cross-sectional views each showing the substrate processing apparatus;

FIG. 7 is a graph showing a potential of a substrate;

FIG. 8 is a graph showing a relation between a flow rate of deionized water and a potential of a substrate in a substrate processing apparatus of a comparative example;

FIG. 9 is a graph showing a film thickness distribution of the deionized water on the substrate;

FIG. 10 is a bottom view of another exemplary upper nozzle; and

FIGS. 11 and 12 are graphs each showing a relation between an inclination angle of a discharge direction and the potential of the substrate.

### DESCRIPTION OF EMBODIMENTS

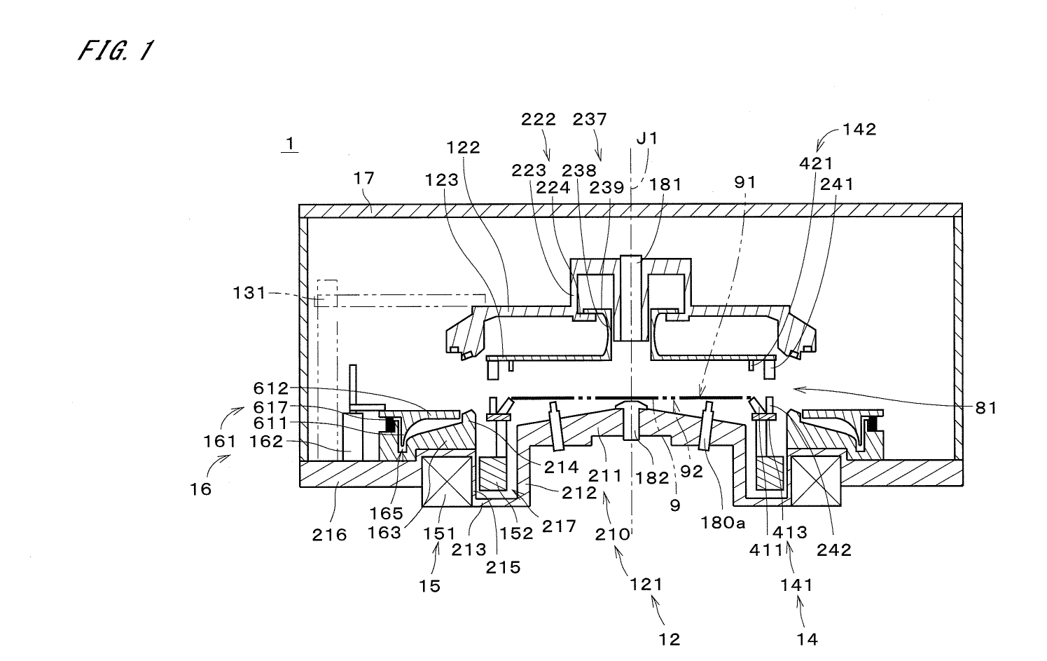

FIG. 1 is a cross-sectional view showing a substrate processing apparatus 1 in accordance with one preferred embodiment of the present invention. The substrate processing apparatus 1 is a single-substrate processing apparatus for supplying a processing liquid to a semiconductor substrate 9 (hereinafter, referred to simply as a “substrate 9”) having a substantially disk-like shape, to thereby process substrates 9 one by one. In the present preferred embodiment, the substrate processing apparatus 1 is used for processing a substrate 9 having a substantially disk-like shape with a diameter of 300 mm. In FIG. 1, hatching of the cross sections of some constituent elements in the substrate processing apparatus 1 is omitted (the same applies to other cross-sectional views).

The substrate processing apparatus 1 includes a chamber 12, a top plate 123, a chamber opening and closing mechanism 131, a substrate holding part 14, a substrate rotating mechanism 15, a liquid receiving part 16, and a cover 17. The cover 17 covers the upper portion and the side of the chamber 12.

The chamber 12 includes a chamber body 121 and a chamber cover 122. The chamber 12 has a substantially cylindrical shape around a central axis J1 directed in a vertical direction. The chamber body 121 includes a chamber bottom 210 and a chamber sidewall 214. The chamber bottom 210 includes a center portion 211 having a substantially annular disk-like shape, an inner sidewall 212 having a substantially cylindrical shape extending downward from an outer edge portion of the center portion 211, an annular bottom 213 having a substantially annular disk-like shape extending outward in a radial direction from a lower end of the inner sidewall 212, an outer sidewall 215 having a substantially cylindrical shape extending upward from an outer edge portion of the annular bottom 213, and a base part 216 having a substantially annular disk-like shape extending outward in the radial direction from an upper end portion of the outer sidewall 215.

The chamber sidewall 214 has an annular shape around the central axis J1. The chamber sidewall 214 protrudes upward from an inner edge portion of the base part 216. A material forming the chamber sidewall 214 also serves as part of the liquid receiving part 16, as described later. In the following description, a space surrounded by the chamber sidewall 214, the outer sidewall 215, the annular bottom 213, the inner sidewall 212, and an outer edge portion of the center portion 211 is referred to as a lower annular space 217.

When the substrate 9 is supported by a substrate supporting part 141 (described later) of the substrate holding part 14, a lower surface 92 of the substrate 9 faces an upper surface of the center portion 211 of the chamber bottom 210. In the following description, the center portion 211 of the chamber bottom 210 is referred to as a “lower surface facing part 211”.

The chamber cover 122 has a substantially disk-like shape perpendicular to the central axis J1, including the upper portion of the chamber 12. The chamber cover 122 closes an upper opening of the chamber body 121. FIG. 1 shows a state where the chamber cover 122 is separated from the chamber body 121. When the chamber cover 122 closes the upper opening of the chamber body 121, an outer edge portion of the chamber cover 122 comes into contact with an upper portion of the chamber sidewall 214.

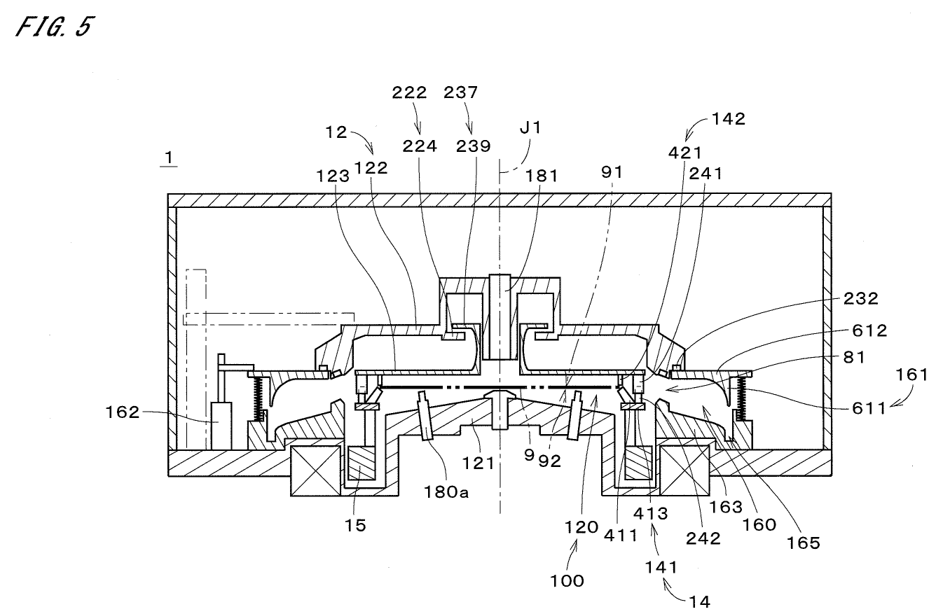

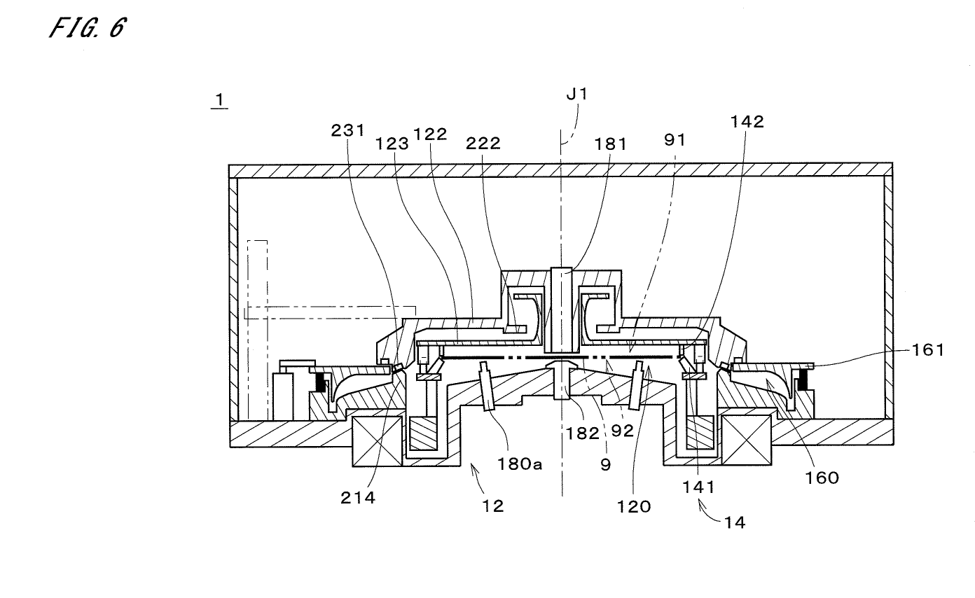

The chamber opening and closing mechanism 131 moves the chamber cover 122 which is a movable part of the chamber 12, relatively to the chamber body 121 which is the other portion of the chamber 12 in the vertical direction. The chamber opening and closing mechanism 131 serves as a cover up-and-down moving mechanism for moving the chamber cover 122 up and down. When the chamber opening and closing mechanism 131 moves the chamber cover 122 in the vertical direction, the top plate 123 is also moved, together with the chamber cover 122, in the vertical direction. When the chamber cover 122 comes into contact with the chamber body 121 to close the upper opening thereof and the chamber cover 122 is pressed toward the chamber body 121, a chamber space 120 (see FIG. 6) which is a sealed internal space is formed inside the chamber 12. In other words, the chamber space 120 is sealed by closing the upper opening of the chamber body 121 by the chamber cover 122. The chamber cover 122 and the chamber body 121 serve as a sealed space forming part which forms the chamber space 120.

The substrate holding part 14 is disposed in the chamber 12 and holds the substrate 9 in a horizontal state. In other words, the substrate 9 is held by the substrate holding part 14, in a state where one main surface 91 (hereinafter, referred to as an “upper surface 91”) thereof on which a fine pattern is formed is directed upward, being perpendicular to the central axis J1. The substrate holding part 14 includes the above-described substrate supporting part 141 for supporting an outer edge portion (i.e., a portion including an outer peripheral edge and the vicinity thereof) of the substrate 9 from below and a substrate retaining part 142 for retaining the outer edge portion of the substrate 9 from above, which is supported by the substrate supporting part 141. The substrate supporting part 141 has a substantially annular shape around the central axis J1. The substrate supporting part 141 includes a supporting part base 413 having a substantially annular disk-like shape around the central axis J1 and a plurality of first contact parts 411 fixed to an upper surface of the supporting part base 413. The substrate retaining part 142 includes a plurality of second contact parts 421 fixed to a lower surface of the top plate 123. Positions of the plurality of second contact parts 421 in a circumferential direction are actually different from those of the plurality of first contact parts 411 in the circumferential direction.

The top plate 123 has a substantially disk-like shape perpendicular to the central axis J1. The top plate 123 is disposed below the chamber cover 122 and above the substrate supporting part 141. The top plate 123 has an opening at its center portion. When the substrate 9 is supported by the substrate supporting part 141, the upper surface 91 of the substrate 9 faces the lower surface of the top plate 123 which is perpendicular to the central axis J1. A diameter of the top plate 123 is larger than that of the substrate 9, and an outer peripheral edge of the top plate 123 is positioned outer than the outer peripheral edge of the substrate 9 in the radial direction all around the circumference.

In the state of FIG. 1, the top plate 123 is supported by the chamber cover 122, being suspended therefrom. The chamber cover 122 has a plate holding part 222 having a substantially annular shape, at its center portion. The plate holding part 222 includes a cylindrical portion 223 having a substantially cylindrical shape around the central axis J1 and a flange portion 224 having a substantially disk-like shape around the central axis J1. The flange portion 224 extends inward in the radial direction from a lower end of the cylindrical portion 223.

The top plate 123 includes a held part 237 having an annular shape. The held part 237 includes a cylindrical portion 238 having a substantially cylindrical shape around the central axis J1 and a flange portion 239 having a substantially disk-like shape around the central axis J1. The cylindrical portion 238 extends upward from an upper surface of the top plate 123. The flange portion 239 extends outward in the radial direction from an upper end of the cylindrical portion 238. The cylindrical portion 238 is positioned inner than the cylindrical portion 223 of the plate holding part 222 in the radial direction. The flange portion 239 is positioned above the flange portion 224 of the plate holding part 222 and faces the flange portion 224 in the vertical direction. When a lower surface of the flange portion 239 of the held part 237 comes into contact with an upper surface of the flange portion 224 of the plate holding part 222, the top plate 123 is attached to the chamber cover 122, being suspended from the chamber cover 122.

On a lower surface of an outer edge portion of the top plate 123, a plurality of first engagement parts 241 are arranged in the circumferential direction, and on an upper surface of the supporting part base 413, a plurality of second engagement parts 242 are arranged in the circumferential direction. The first engagement parts 241 and the second engagement parts 242 are actually arranged at different positions from the positions of the plurality of first contact parts 411 of the substrate supporting part 141 and the plurality of second contact parts 421 of the substrate retaining part 142 in the circumferential direction. It is preferable that these engagement parts should be provided in three or more pairs, and in the present preferred embodiment, four pairs are provided. At a lower portion of the first engagement part 241, provided is a recessed portion which is recessed upward. The second engagement part 242 protrudes upward from the supporting part base 413.

The substrate rotating mechanism 15 is a so-called hollow motor. The substrate rotating mechanism 15 includes a stator part 151 having an annular shape around the central axis J1 and a rotor part 152 having an annular shape. The rotor part 152 includes a permanent magnet having a substantially annular shape. A surface of the permanent magnet is molded of a PTFE (polytetrafluoroethylene) resin. The rotor part 152 is disposed inside the lower annular space 217 in the chamber 12. Above the rotor part 152, attached is the supporting part base 413 of the substrate supporting part 141 with a connecting member interposed therebetween. The supporting part base 413 is disposed above the rotor part 152.

The stator part 151 is disposed in the periphery of the rotor part 152 outside the chamber 12, i.e., disposed on the outer side of the rotor part 152 in the radial direction. In the present preferred embodiment, the stator part 151 is fixed to the outer sidewall 215 and the base part 216 of the chamber bottom 210 and positioned below the liquid receiving part 16. The stator part 151 includes a plurality of coils arranged in the circumferential direction around the central axis J1.

By supplying current to the stator part 151, a rotating force is generated around the central axis J1 between the stator part 151 and the rotor part 152. The rotor part 152 is thereby rotated in a horizontal state around the central axis J1. With a magnetic force exerted between the stator part 151 and the rotor part 152, the rotor part 152 floats in the chamber 12, not being in direct or indirect contact with the chamber 12, and rotates the substrate 9 together with the substrate supporting part 141 around the central axis J1, being in a floating state.

The liquid receiving part 16 includes a cup part 161, a cup moving mechanism 162, and a cup facing part 163. The cup part 161 has an annular shape around the central axis J1 and is positioned outer than the chamber 12 in the radial direction all around the circumference. The cup moving mechanism 162 moves the cup part 161 in the vertical direction. The cup moving mechanism 162 is positioned outer than the cup part 161 in the radial direction. The cup moving mechanism 162 is disposed at the different position from the position of the above-described chamber opening and closing mechanism 131 in the circumferential direction. The cup facing part 163 is positioned below the cup part 161 and faces the cup part 161 in the vertical direction. The cup facing part 163 is part of a material which forms the chamber sidewall 214. The cup facing part 163 has an annular liquid receiving recessed portion 165 positioned outer than the chamber sidewall 214 in the radial direction.

The cup part 161 includes a sidewall 611, an upper surface part 612, and a bellows 617. The sidewall 611 has a substantially cylindrical shape around the central axis J1. The upper surface part 612 has a substantially annular disk-like shape around the central axis J1, extending from an upper end portion of the sidewall 611 inward and outward in the radial direction. A lower portion of the sidewall 611 is positioned inside the liquid receiving recessed portion 165 of the cup facing part 163.

The bellows 617 has a substantially cylindrical shape around the central axis J1 and is extensible in the vertical direction. The bellows 617 is provided outer than the sidewall 611 in the radial direction, all around the circumference of the sidewall 611. The bellows 617 is formed of a material which does not allow the passage of gas and liquid. An upper end portion of the bellows 617 is connected to a lower surface of an outer edge portion of the upper surface part 612 all around the circumference. In other words, the upper end portion of the bellows 617 is indirectly connected to the sidewall 611 with the upper surface part 612 interposed therebetween. A connecting portion between the bellows 617 and the upper surface part 612 is sealed, and this prevents the passage of gas and liquid. A lower end portion of the bellows 617 is indirectly connected to the chamber body 121 with the cup facing part 163 interposed therebetween. Also at a connecting portion between the lower end portion of the bellows 617 and the cup facing part 163, the passage of gas and liquid is prevented.

An upper nozzle 181 having a substantially columnar shape around the central axis J1 is attached to a center portion of the chamber cover 122. The upper nozzle 181 is so fixed to the chamber cover 122 as to face the center portion of the upper surface 91 of the substrate 9. The upper nozzle 181 is insertable into the opening of the center portion of the top plate 123. At a center portion of the lower surface facing part 211 of the chamber bottom 210, a lower nozzle 182 is attached. The lower nozzle 182 has a liquid discharge port at its center portion and faces the center portion of the lower surface 92 of the substrate 9. At the lower surface facing part 211, a plurality of heating gas supply nozzles 180a are further provided. The plurality of heating gas supply nozzles 180a are disposed, for example, at regular angular intervals in the circumferential direction around the central axis J1.

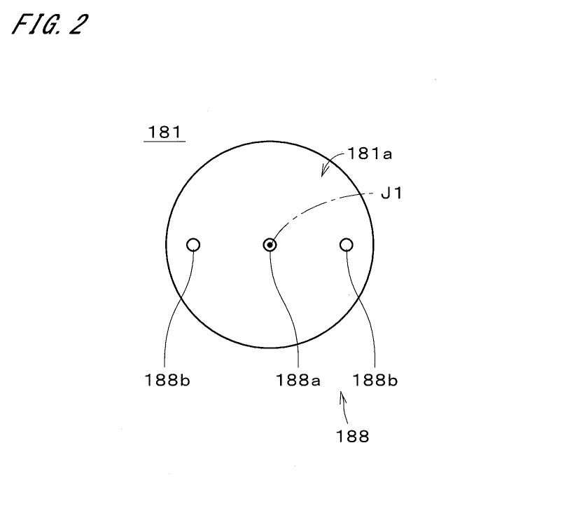

FIG. 2 is a bottom view of the upper nozzle 181. A bottom surface 181a of the upper nozzle 181 has a substantially circular shape around the central axis J1. In the bottom surface 181a, provided are a plurality of discharge ports 188 for discharging a liquid. The plurality of discharge ports 188 include a central discharge port 188a disposed at a center (i.e., substantially on the central axis J1) and a plurality of peripheral discharge ports 188b disposed around the central discharge port 188a. The peripheral discharge ports 188b are disposed at regular angular intervals on a circumference around the central axis J1.

In an example of FIG. 2, two peripheral discharge ports 188b are disposed at intervals of 180 degrees in the circumferential direction around the central axis J1. In other words, the two peripheral discharge ports 188b are disposed at positions facing each other with the central axis J1 as the center. Further, preferably, the plurality of discharge ports 188 are disposed within a circle having a radius smaller than or equal to 60 mm around the central axis J1, i.e., within a circle having a radius smaller than or equal to 40% of a radius of the substrate around the central axis J1. Each of the discharge ports 188 has a diameter of about 4 mm, and a center-to-center distance between the central discharge port 188a and each of the peripheral discharge ports 188b (i.e., a distance between the center of the central discharge port 188a and that of each peripheral discharge port 188b in the radial direction) is about 30 mm.

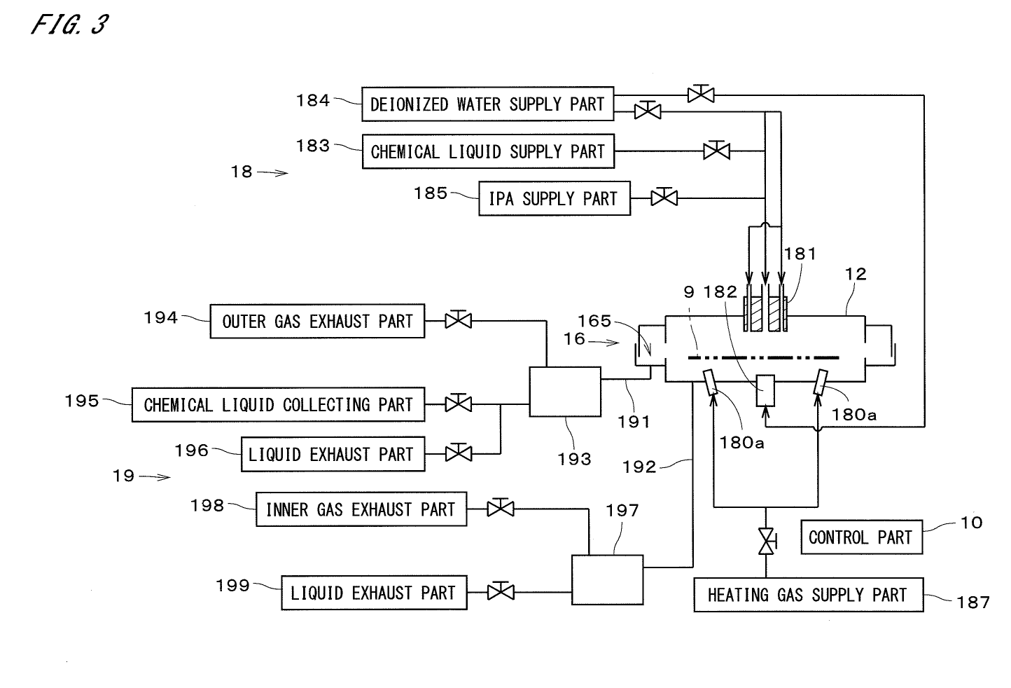

FIG. 3 is a block diagram showing a gas-liquid supply part 18 and a gas-liquid exhaust part 19 included in the substrate processing apparatus 1. The gas-liquid supply part 18 includes a chemical liquid supply part 183, a deionized water supply part 184, an IPA supply part 185, and a heating gas supply part 187, besides the upper nozzle 181, the lower nozzle 182, and the heating gas supply nozzles 180a described above.

The chemical liquid supply part 183 is connected to the upper nozzle 181 with a valve interposed therebetween. The deionized water supply part 184 and the IPA supply part 185 are connected to the upper nozzle 181 each with a valve interposed therebetween. The lower nozzle 182 is connected to the deionized water supply part 184 with a valve interposed therebetween. The plurality of heating gas supply nozzles 180a are connected to the heating gas supply part 187 with a valve interposed therebetween.

A first exhaust path 191 connected to the liquid receiving recessed portion 165 of the liquid receiving part 16 is connected to a gas-liquid separating part 193. The gas-liquid separating part 193 is connected to an outer gas exhaust part 194, a chemical liquid collecting part 195, and a liquid exhaust part 196 each with a valve interposed therebetween. A second exhaust path 192 connected to the chamber bottom 210 of the chamber 12 is connected to a gas-liquid separating part 197. The gas-liquid separating part 197 is connected to an inner gas exhaust part 198 and a liquid exhaust part 199 each with a valve interposed therebetween. The constituent elements in the gas-liquid supply part 18 and the gas-liquid exhaust part 19 are controlled by a control part 10. The chamber opening and closing mechanism 131, the substrate rotating mechanism 15, and the cup moving mechanism 162 (see FIG. 1) are also controlled by the control part 10.

A chemical liquid supplied from the chemical liquid supply part 183 to the upper nozzle 181 is discharged toward the center portion of the upper surface 91 of the substrate 9 from the central discharge port 188a of the upper nozzle 181 (see FIG. 2). The chemical liquid supplied from the chemical liquid supply part 183 onto the substrate 9 through the upper nozzle 181 is a processing liquid to be used for processing the substrate by utilizing chemical reaction, which is, for example, an etching solution such as hydrofluoric acid, a tetramethylammonium hydroxide solution, or the like.

The deionized water supply part 184 supplies deionized water (DIW) onto the substrate 9 through the upper nozzle 181 and the lower nozzle 182. The deionized water supplied from the deionized water supply part 184 to the upper nozzle 181 is discharged from the plurality of discharge ports 188 (i.e., the central discharge port 188a and the peripheral discharge ports 188b) of the upper nozzle 181 toward the center portion of the upper surface 91 of the substrate 9 in a discharge direction substantially perpendicular to the upper surface 91. The deionized water supplied from the deionized water supply part 184 to the lower nozzle 182 is discharged from a discharge port of the lower nozzle 182 toward the center portion of the lower surface 92 of the substrate 9.

Isopropyl alcohol (IPA) supplied from the IPA supply part 185 to the upper nozzle 181 is discharged from the central discharge port 188a of the upper nozzle 181 toward the center portion of the upper surface 91 of the substrate 9. In the substrate processing apparatus 1, a processing liquid supply part for supplying any processing liquid other than the above processing liquids (the above-described chemical liquid, deionized water, and IPA) may be provided.

The heating gas supply part 187 supplies heated gas (e.g., a high-temperature inert gas) onto the lower surface 92 of the substrate 9 through the plurality of heating gas supply nozzles 180a. In the present preferred embodiment, the gas used in the heating gas supply part 187 is nitrogen gas (N₂), but any gas other than nitrogen gas may be used. Further, in the case where the heated inert gas is used in the heating gas supply part 187, the explosion-proof countermeasure in the substrate processing apparatus 1 can be simplified or is not needed.

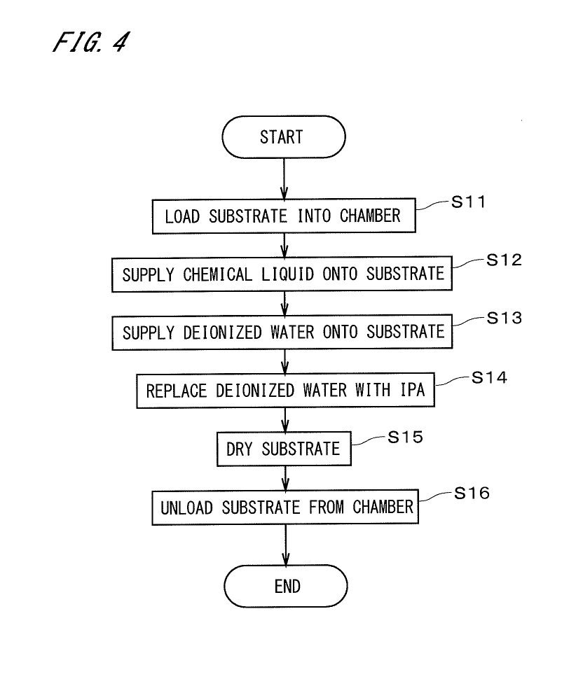

FIG. 4 is a flowchart showing an operation flow for processing the substrate 9 in the substrate processing apparatus 1. In the substrate processing apparatus 1, in a state where the chamber cover 122 is separated from the chamber body 121 and positioned thereabove and the cup part 161 is separated from the chamber cover 122 and positioned therebelow as shown in FIG. 1, the substrate 9 is loaded into the chamber 12 by an external transfer mechanism and supported by the substrate supporting part 141 from below (Step S11). Hereinafter, the state of the chamber 12 and the cup part 161 shown in FIG. 1 is referred to as an “open state”. An opening between the chamber cover 122 and the chamber sidewall 214 has an annular shape around the central axis J1 and is hereinafter referred to as an “annular opening 81”. In the substrate processing apparatus 1, when the chamber cover 122 is separated from the chamber body 121, the annular opening 81 is formed around the substrate 9 (in other words, outer than the substrate 9 in the radial direction). In Step S11, the substrate 9 is loaded through the annular opening 81.

After the substrate 9 is loaded, the cup part 161 moves upward from the position shown in FIG. 1 up to the position shown in FIG. 5, to be positioned outer than the annular opening 81 in the radial direction all around the circumference. In the following description, the state of the chamber 12 and the cup part 161 shown in FIG. 5 is referred to as a “first sealed state”. Further, the position of the cup part 161 shown in FIG. 5 is referred to as a “liquid receiving position” and the position of the cup part 161 shown in FIG. 1 is referred to as an “escape position”. The cup moving mechanism 162 moves the cup part 161 in the vertical direction between the liquid receiving position which is outer than the annular opening 81 in the radial direction and the escape position below the liquid receiving position.

In the cup part 161 positioned at the liquid receiving position, the sidewall 611 faces the annular opening 81 in the radial direction. Further, an upper surface of an inner edge portion of the upper surface part 612 is in contact with a lip seal 232 positioned at a lower end of an outer edge portion of the chamber cover 122 all around the circumference. Between the chamber cover 122 and the upper surface part 612 of the cup part 161, formed is a seal part for preventing the passage of gas and liquid. This forms a sealed space (hereinafter, referred to as an “enlarged sealed space 100”) surrounded by the chamber body 121, the chamber cover 122, the cup part 161, and the cup facing part 163. The enlarged sealed space 100 is a space which is formed when the chamber space 120 between the chamber cover 122 and the chamber body 121 and a side space 160 surrounded by the cup part 161 and the cup facing part 163 communicate with each other through the annular opening 81.

In the first sealed state, the plurality of second contact parts 421 of the substrate retaining part 142 are in contact with the outer edge portion of the substrate 9. On the lower surface of the top plate 123 and on the supporting part base 413 of the substrate supporting part 141, provided are a plurality of pairs of magnets (not shown) in each of which two magnets face each other in the vertical direction. Hereinafter, each pair of magnets is referred to also as “a magnet pair”. In the substrate processing apparatus 1, a plurality of magnet pairs are disposed at regular angular intervals at positions different from those of the first contact parts 411, the second contact parts 421, the first engagement parts 241, and the second engagement parts 242 in the circumferential direction. In a state where the substrate retaining part 142 is in contact with the substrate 9, with a magnetic force (attractive force) exerted between each magnet pair, a downward force is exerted on the top plate 123. The substrate retaining part 142 thereby presses the substrate 9 toward the substrate supporting part 141.

In the substrate processing apparatus 1, the substrate retaining part 142 presses the substrate 9 toward the substrate supporting part 141 with the weight of the top plate 123 and the magnetic forces of the magnet pairs, and it is thereby possible to strongly hold the substrate 9 being sandwiched from above and below by the substrate retaining part 142 and the substrate supporting part 141.

In the first sealed state, the flange portion 239 of the held part 237 is separated above from the flange portion 224 of the plate holding part 222, and the plate holding part 222 is out of contact with the held part 237. In other words, the plate holding part 222 releases holding of the top plate 123. Therefore, the top plate 123, being independent of the chamber cover 122, is rotated by the substrate rotating mechanism 15, together with the substrate holding part 14 and the substrate 9 held by the substrate holding part 14.

Further, in the first sealed state, the second engagement part 242 engages with a lower recessed portion of the first engagement part 241. The top plate 123 thereby engages with the supporting part base 413 of the substrate supporting part 141 in the circumferential direction around the central axis J1. In other words, the first engagement part 241 and the second engagement part 242 serve as a position regulating member for regulating a relative position of the top plate 123 with respect to the substrate supporting part 141 in a rotation direction (in other words, for fixing a relative position in the circumferential direction). When the chamber cover 122 moves down, the substrate rotating mechanism 15 controls a rotation position of the supporting part base 413 so that the first engagement part 241 may engage with the second engagement part 242.

Subsequently, rotation of the substrate 9 is started by the substrate rotating mechanism 15 at a constant number of rotation (relatively low number of rotation, and hereinafter, referred to as “the steady number of rotation”). Next, heated gas (hereinafter, referred to as a “heating gas”) is ejected from the plurality of heating gas supply nozzles 180a toward the lower surface 92 of the substrate 9 being rotated, and the exhaust of gas from the enlarged sealed space 100 by the outer gas exhaust part 194 is started. The substrate 9 is thereby heated. Then, the supply of the chemical liquid is started toward the upper surface 91 of the substrate 9 being rotated, from the central discharge port 188a of the upper nozzle 181 (see FIG. 2). The discharge of the chemical liquid toward the upper surface 91 of the substrate 9 is performed only on the center portion of the substrate 9, not on any portion other than the center portion. The chemical liquid from the upper nozzle 181 is continuously supplied like a liquid column onto the upper surface 91 of the substrate 9 being rotated. With the rotation of the substrate 9, the chemical liquid on the upper surface 91 spreads toward the outer peripheral portion of the substrate 9, and the entire upper surface 91 is covered with the chemical liquid.

The ejection of the heating gas from the heating gas supply nozzles 180a also continues while the chemical liquid is supplied from the upper nozzle 181. Etching is thereby performed on the upper surface 91 of the substrate 9 by using the chemical liquid while the substrate 9 is heated to approximately a desired temperature. As a result, it is possible to improve the uniformity of a chemical liquid processing on the substrate 9. Since the lower surface of the top plate 123 is close to the upper surface 91 of the substrate 9, the etching of the substrate 9 is performed in a very narrow space between the lower surface of the top plate 123 and the upper surface 91 of the substrate 9.

In the enlarged sealed space 100, the chemical liquid scattered from the upper surface 91 of the substrate 9 being rotated is received by the cup part 161 through the annular opening 81 and led toward the liquid receiving recessed portion 165. The chemical liquid led to the liquid receiving recessed portion 165 flows into the gas-liquid separating part 193 through the first exhaust path 191 shown in FIG. 3. In the chemical liquid collecting part 195, the chemical liquid is collected from the gas-liquid separating part 193, and after removing impurities or the like from the chemical liquid through a filter or the like, the chemical liquid is reused.

After a predetermined time (e.g., 60 to 120 seconds) elapses from the start of the supply of the chemical liquid from the upper nozzle 181, the supply of the chemical liquid from the upper nozzle 181 and the supply of the heating gas from the heating gas supply nozzles 180a are stopped. Then, the substrate rotating mechanism 15 increases the number of rotation of the substrate 9 to be higher than the steady number of rotation for a predetermined time period (e.g., 1 to 3 seconds), to thereby remove the chemical liquid from the substrate 9.

Subsequently, the chamber cover 122 and the cup part 161 synchronously moves down. Then, as shown in FIG. 6, a lip seal 231 positioned at the lower end of the outer edge portion of the chamber cover 122 comes into contact with the upper portion of the chamber sidewall 214, to thereby close the annular opening 81, and the chamber space 120 becomes sealed, being isolated from the side space 160. The cup part 161 is located at the escape position like in the state of FIG. 1. Hereinafter, the state of the chamber 12 and the cup part 161 shown in FIG. 6 is referred to as a “second sealed state”. In the second sealed state, the substrate 9 directly faces an inner wall of the chamber 12, and there is not any other liquid receiving part therebetween.

Also in the second sealed state, like in the first sealed state, the substrate retaining part 142 presses the substrate 9 toward the substrate supporting part 141, and it is thereby possible to strongly hold the substrate 9 being sandwiched from above and below by the substrate retaining part 142 and the substrate supporting part 141. Further, the plate holding part 222 releases holding of the top plate 123, and the top plate 123, being independent of the chamber cover 122, is rotated together with the substrate holding part 14 and the substrate 9.

After the chamber space 120 becomes sealed, the exhaust of the gas by the outer gas exhaust part 194 (see FIG. 3) is stopped and the exhaust of gas from the chamber space 120 by the inner gas exhaust part 198 is started. Then, the supply of the deionized water onto the substrate 9 is started by the deionized water supply part 184 (Step S13).

The deionized water from the deionized water supply part 184 is continuously supplied onto the center portion of the upper surface 91 of the substrate 9 from the plurality of discharge ports 188 of the upper nozzle 181 (see FIG. 2). Further, the deionized water from the deionized water supply part 184 is continuously supplied also onto the center portion of the lower surface 92 of the substrate 9 from the lower nozzle 182. The deionized water discharged from the upper nozzle 181 and the lower nozzle 182 is supplied onto the substrate 9 as a cleaning solution.

In the present preferred embodiment, the flow rate of the deionized water to be supplied from the upper nozzle 181 onto the upper surface 91 of the substrate 9 is about 2 liters per minute. Specifically, the flow rate of the deionized water to be supplied from the central discharge port 188a shown in FIG. 2 is about 1 liter per minute, and the flow rate of the deionized water to be supplied from each peripheral discharge port 188b is about 0.5 liters per minute. The flow rate of the deionized water to be discharged from each of the plurality of discharge ports 188 is, preferably, set to be lower than or equal to 1 liter per minute.

With the rotation of the substrate 9 shown in FIG. 6, the deionized water spreads toward the respective outer peripheral portions of the upper surface 91 and the lower surface 92 and is scattered outward from the outer peripheral edge of the substrate 9. The deionized water scattered from the substrate 9 is received by the inner wall of the chamber 12 (i.e., the respective inner walls of the chamber cover 122 and the chamber sidewall 214) and discarded through the second exhaust path 192, the gas-liquid separating part 197, and the liquid exhaust part 199 shown in FIG. 3 (the same applies to a drying process on the substrate 9 described later). With this operation, as well as a cleaning process on the substrate 9 by using the deionized water, cleaning of the inside of the chamber 12 is substantially performed.

After a predetermined time elapses from the start of supply of the deionized water, the supply of the deionized water from the deionized water supply part 184 is stopped. Then, the heating gas is ejected from the plurality of heating gas supply nozzles 180a toward the lower surface 92 of the substrate 9. The substrate 9 is thereby heated.

Subsequently, the IPA is supplied onto the upper surface 91 of the substrate 9 from the upper nozzle 181, and the deionized water is replaced with the IPA on the upper surface 91 (Step S14). After a predetermined time elapses from the start of supply of the IPA, the supply of the IPA from the IPA supply part 185 is stopped. After that, while the ejection of the heating gas from the heating gas supply nozzles 180a continues, the number of rotation of the substrate 9 is increased to be sufficiently higher than the steady number of rotation. The IPA is thereby removed from the substrate 9, and drying of the substrate 9 is performed (Step 15). After a predetermined time elapses from the start of drying of the substrate 9, the rotation of the substrate 9 is stopped. The drying of the substrate 9 may be performed in a reduced pressure atmosphere in which the pressure of the chamber space 120 is reduced by the inner gas exhaust part 198 to be lower than the atmosphere pressure.

After that, the chamber cover 122 and the top plate 123 move up, and the chamber 12 is brought into the open state as shown in FIG. 1. In Step S15, since the top plate 123 is rotated together with the substrate supporting part 141, almost no liquid remains on the lower surface of the top plate 123 and therefore, no liquid drops from the top plate 123 onto the substrate 9 when the chamber cover 122 moves up. The substrate 9 is unloaded from the chamber 12 by the external transfer mechanism (Step S16).

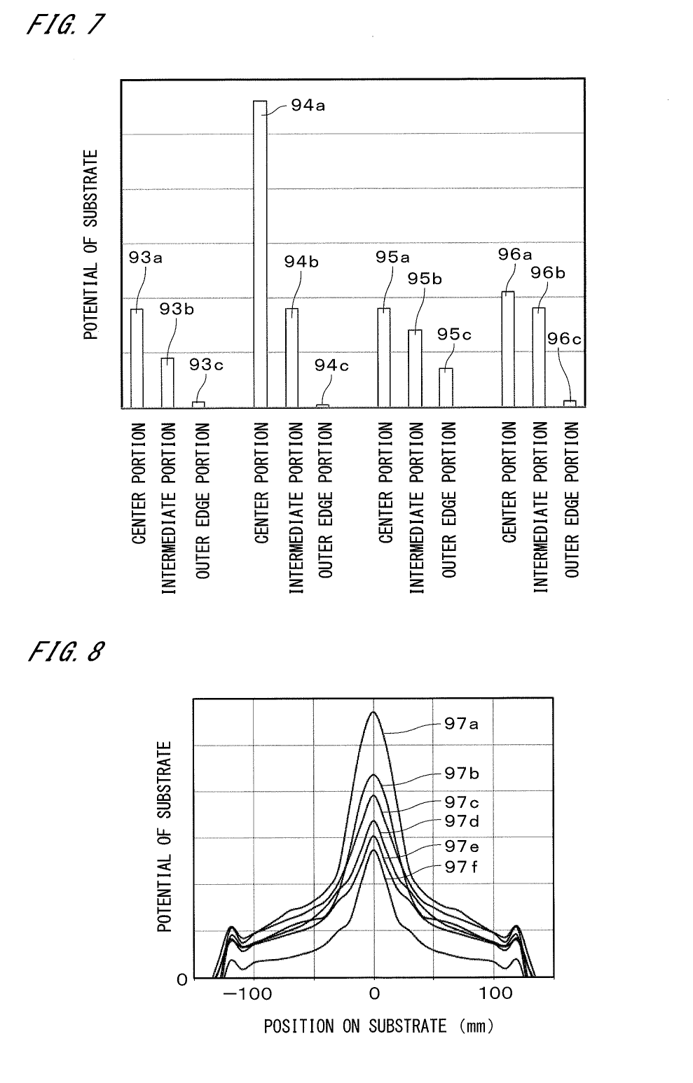

In the cleaning process of the substrate by using the deionized water, contact between the substrate and the deionized water having high electrical resistivity, or the like, causes the substrate to be electrically charged (electrified). FIG. 7 is a graph showing a potential of the substrate 9 after the cleaning process in the substrate processing apparatus 1 and a potential of a substrate after a cleaning process in a substrate processing apparatus of a comparative example. The substrate processing apparatus of the comparative example has almost the same constitution as that of the substrate processing apparatus 1 shown in FIG. 1 except that the upper nozzle in the substrate processing apparatus of the comparative example is provided with only one discharge port for discharging deionized water on the central axis. In FIG. 7, the vertical axis represents an absolute value of a potential (hereinafter, referred to simply as a “potential”) on the substrate.

In FIG. 7, three bars 93a to 93c on the leftmost side represent a potential at the center portion of the substrate 9 after being subjected to the cleaning process performed in the substrate processing apparatus 1 shown in FIG. 1, a potential at an intermediate portion between the center portion and the outer edge portion, and a potential at the outer edge portion, respectively. Next three bars 94a to 94c represent respective potentials at the center portion, the intermediate portion, and the outer edge portion of the substrate after being subjected to the cleaning process performed while discharging deionized water of 2 liters per minute from the above-described one discharge port of the upper nozzle in the substrate processing apparatus of the comparative example. Further next three bars 95a to 95c represent respective potentials at the center portion, the intermediate portion, and the outer edge portion of the substrate after being subjected to the cleaning process performed while discharging deionized water of 1 liter per minute from the discharge port of the upper nozzle in the substrate processing apparatus of the comparative example. Three bars 96a to 96c on the rightmost side represent respective potentials at the center portion, the intermediate portion, and the outer edge portion of the substrate after being subjected to the cleaning process performed while discharging deionized water of 0.5 liters per minute from the discharge port of the upper nozzle in the substrate processing apparatus of the comparative example.

As shown in FIG. 7, in the substrate processing apparatus 1 shown in FIG. 1, the potential at the center portion against which the deionized water discharged from the upper nozzle 181 collides is the highest, and the potential becomes lower as it goes toward the outer edge portion. The same applies to the potentials in the substrate processing apparatus of the comparative example. Further, in the substrate processing apparatus of the comparative example, as the flow rate of the deionized water supplied onto the substrate from the upper nozzle decreases, the potential on the substrate becomes lower.

In the substrate processing apparatus 1 of FIG. 1, the deionized water of 2 liters per minute is supplied onto the substrate 9 from the upper nozzle 181 as mentioned above, and when attention is paid only to the amount of deionized water supplied per unit time from the upper nozzle 181 (i.e., the flow rate of the deionized water from the upper nozzle 181), the condition is the same as that of the bars 94a to 94c shown in FIG. 7 which is used in the substrate processing apparatus of the comparative example. In the substrate processing apparatus 1, however, the upper nozzle 181 has the plurality of discharge ports 188, and the deionized water of 1 liter per minute is discharged from the central discharge port 188a and the deionized water of 0.5 liters per minute is discharged from each peripheral discharge port 188b.

Thus, in the substrate processing apparatus 1, by providing the plurality of discharge ports 188 in the upper nozzle 181 and reducing the flow rate of the deionized water discharged from each peripheral discharge port 188b, even if the amount of deionized water supplied from the upper nozzle 181 is the same, it is possible to reduce the potential on the substrate 9, and particularly the potential at the center portion of the substrate 9. Particularly, by setting the flow rate of the deionized water discharged from each peripheral discharge port 188b to be lower than or equal to 1 liter per minute, it is possible to more efficiently suppress electrification at the center portion of the substrate 9.

On the other hand, when the flow rate of the deionized water to be supplied to the substrate from the upper nozzle decreases, there is a possibility that cleaning of the substrate may insufficiently performed and particles or the like may remain on the substrate after the cleaning. Such insufficient cleaning of the substrate is more remarkable at the intermediate portion and the outer edge portion away from the center portion of the substrate and this is thought to be caused by the shortage of film thickness of the deionized water at the intermediate portion and the outer edge portion of the substrate. In the substrate processing apparatus 1 of FIG. 1, as mentioned above, by providing the plurality of discharge ports 188 in the upper nozzle 181, the flow rate of the deionized water to be supplied onto the center portion of the substrate 9 from the upper nozzle 181 can be ensured, with the flow rate of the deionized water from each discharge port 188 reduced. It is thereby possible to perform appropriate cleaning of the upper surface 91 of the substrate 9 while suppressing electrification at the center portion of the substrate 9.

As described above, in the upper nozzle 181, provided are the central discharge port 188a disposed at the center and the plurality of peripheral discharge ports 188b disposed at regular angular intervals on a circumference around the central axis J1. As the position on the substrate 9 at which the deionized water is discharged is closer to the center of the substrate 9, the deionized water supplied from the upper nozzle 181 onto the substrate 9 moves longer on the upper surface 91 of the substrate 9 and contributes more to the cleaning of the substrate 9. In the substrate processing apparatus 1, by discharging the deionized water onto the substantial center of the substrate 9 from the central discharge port 188a, it is possible to improve the efficiency of the cleaning of the substrate 9. Further, the plurality of peripheral discharge ports 188b are disposed at preferable positions in the radial direction around the central axis J1, and the deionized water can be supplied from these peripheral discharge ports 188b almost uniformly in the circumferential direction around the central axis J1. As a result, it is possible to improve the uniformity of the cleaning of the upper surface 91 of the substrate 9.

FIG. 8 is a graph showing a relation between th flow rate of the deionized water supplied onto the substrate from the upper nozzle and the potential at each position on the upper surface of the substrate in the substrate processing apparatus of the above-described comparative example. In FIG. 8, the horizontal axis represents a position on the substrate, and specifically a coordinate of each position on the substrate in the radial direction with the center of the substrate as “0” (i.e., a distance from the center of the substrate). The vertical axis of FIG. 8 represents an absolute value of a potential (hereinafter, referred to simply as a “potential”) at each position on the substrate. Lines 97a to 97f indicate respective potentials in the cases where the flow rate of the deionized water from the upper nozzle 181 is 2.5 liters, 2 liters, 1.5 liters, 1 liter, 0.5 liters, and 0.2 liters per minute.

In the substrate processing apparatus of the comparative example, it can be seen that great electrification is not generated on the substrate when the flow rate of the deionized water from the upper nozzle is lower than or equal to 0.2 liters per minute. In the substrate processing apparatus 1 of FIG. 1, the flow rate of the deionized water from the central discharge port 188a is 1 liter per minute as mentioned above. As indicated by the line 97d in FIG. 8, an area (hereinafter, referred to as an “excessive-potential area”) where the potential which is generated when the deionized water is discharged in a flow rate of 1 liter per minute from one discharge port exceeds the maximum potential which is generated when the deionized water is discharged in a flow rate of 0.2 liters per minute from one discharge port is within a circular range having a radius of about 10 mm from the center of the substrate 9. In the substrate processing apparatus 1 of FIG. 1, it is preferable that the center-to-center distance between the central discharge port 188a and each peripheral discharge port 188b should be longer than or equal to 20 mm so that the excessive-potential area in discharging the deionized water from the central discharge port 188a and that in discharging the deionized water from each peripheral discharge port 188b may not overlap with each other. It is thereby possible to further suppress electrification at the center portion of the substrate 9.

In the substrate processing apparatus 1, it is required to reduce the time needed for the cleaning process using the deionized water in order to prevent corrosion of wires on the substrate 9 and reduce the time needed to process the substrate 9. On the other hand, when the time for cleaning is short, the possibility of occurrence of insufficient cleaning due to the above-mentioned shortage of film thickness, or the like, at the intermediate portion and the outer edge portion of the substrate 9 increases.

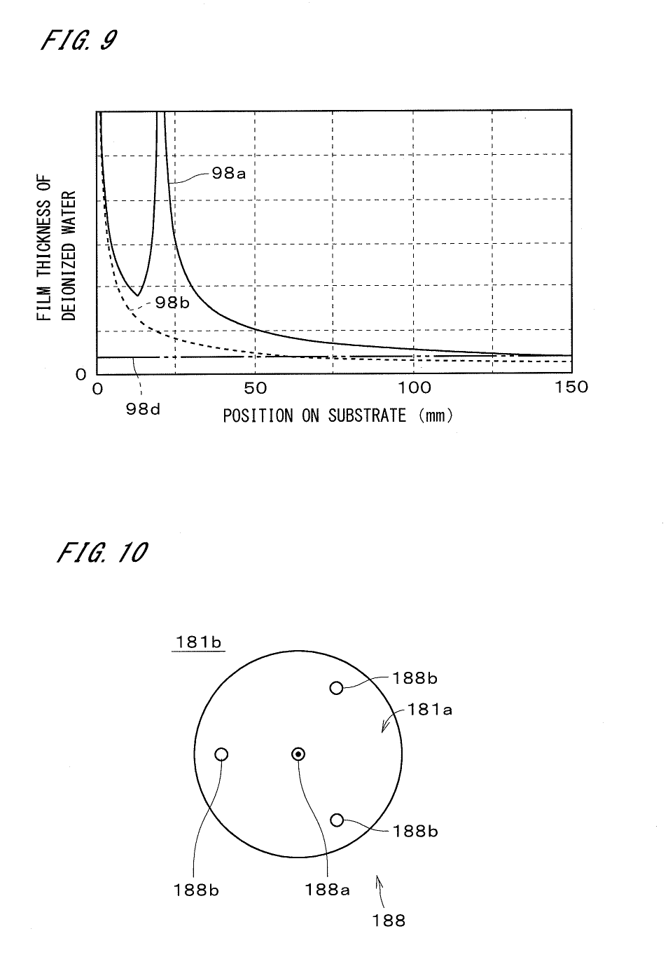

FIG. 9 is a graph showing a film thickness distribution of the deionized water on the substrate 9. In FIG. 9, the horizontal axis represents a distance between each position on the substrate 9 and the center of the substrate 9, and the vertical axis represents a film thickness of the deionized water at each position on the substrate 9. In FIG. 9, a line 98a indicates a film thickness distribution in a case where the deionized water is supplied from an upper nozzle 181b shown in FIG. 10, instead of the upper nozzle 181 shown in FIG. 2, onto the center portion of the substrate 9 substantially perpendicularly to the upper surface 91 of the substrate 9 in the substrate processing apparatus 1. The upper nozzle 181b discharges the deionized water toward the center portion of the upper surface 91 of the substrate 9 from four discharge ports 188 provided in the bottom surface 181a thereof. The four discharge ports 188 include one central discharge port 188a disposed at the center and three peripheral discharge ports 188b disposed at regular angular intervals (i.e., at intervals of 120 degrees) on a circumference around the central axis J1. The center-to-center distance between the central discharge port 188a and each peripheral discharge port 188b is about 20 mm.

In FIG. 9, the line 98a indicates a film thickness distribution in a case where the deionized water of 0.5 liters per minute is discharged from each discharge port 188, which is obtained by simulation. In this case, the flow rate of the deionized water supplied onto the substrate 9 from the upper nozzle 181b is 2 liters per minute. A line 98b indicates a film thickness distribution in a case where the deionized water of 0.5 liters per minute is discharged only from the central discharge port 188a and no deionized water is discharged from the peripheral discharge ports 188b, which is obtained by simulation.

Further, a line 98d indicates a film thickness distribution in a case where there is a possibility of insufficient cleaning due to thinned film thickness of the deionized water at the intermediate portion and the outer edge portion of the substrate 9. In FIG. 9, the position at which the line 98b intersects the line 98d is a position away from the center of the substrate 9 by about 60 mm. On the line 98a, at the position away from the center of the substrate 9 by about 60 mm, the film thickness of the deionized water is larger than the threshold value indicated by the line 98d, by the effect of the deionized water supplied from the peripheral discharge ports 188b. It is thereby possible to suppress the occurrence of insufficient cleaning at the intermediate portion and the outer edge portion of the substrate 9.

Thus, in the substrate processing apparatus 1, by disposing the plurality of discharge ports 188 within a circle having a radius smaller than or equal to 60 mm around the central axis J1, in other words, by discharging the deionized water from the plurality of discharge ports 188 toward the substrate 9 within the circle having a radius smaller than or equal to 60 mm around the central axis J1, it is possible to prevent the film thickness of the deionized water on the substrate 9 from becoming smaller than the above threshold value. As a result, it is possible to suppress the occurrence of insufficient cleaning of the substrate 9. When attention is paid to a relation between the position of the discharge port 188 and the radius of the substrate 9, by disposing the plurality of discharge ports 188 within a circle having a radius smaller than or equal to 40% of a radius of the substrate 9 around the central axis J1, as described above, it is possible to suppress the occurrence of insufficient cleaning of the substrate 9. In the substrate processing apparatus 1, the same applies to the case where the upper nozzle 181 shown in FIG. 2 is used, instead of the upper nozzle 181b shown in FIG. 10, in the substrate processing apparatus 1.

Though the deionized water is discharged from the plurality of discharge ports 188 of the upper nozzle 181 or 181b onto the upper surface 91 of the substrate 9 substantially perpendicularly thereto in the above description, the discharge direction of the deionized water from the discharge ports 188 may be inclined with respect to the central axis J1. FIG. 11 is a graph showing a potential distribution of the substrate 9 in a case where the deionized water is discharged toward the center of the substrate 9 from one discharge port. In FIG. 11, the horizontal axis represents a coordinate of each position on the substrate 9 in the radial direction with the center of the substrate 9 as “0”, and the vertical axis represents an absolute value of a potential (hereinafter, referred to simply as a “potential”) at each position of the substrate 9.

Lines 99a to 99c indicate respective potentials in the cases where the inclination angle of the discharge direction of the deionized water from the above one discharge port with respect to the central axis J1 (i.e., an angle formed by the discharge direction and the central axis J1) is 0 degrees, 30 degrees, and 60 degrees. The inclination angle of 0 degrees refers to a condition where the discharge direction is parallel to the central axis J1 and the deionized water is discharged on the upper surface 91 of the substrate 9 substantially perpendicularly thereto. The inclination angle of 30 degrees refers to a condition where an angle formed by a normal extending in the vertical direction at an intersection point where a discharge axis extending from the discharge port in the discharge direction intersects the upper surface 91 of the substrate 9 and the discharge axis is 30 degrees, and in other words, an angle formed by a perspective discharge axis obtained by projecting the discharge axis on the upper surface 91 of the substrate 9 in the vertical direction and the discharge axis is 60 degrees. The inclination angle of 60 degrees refers to a condition where an angle formed by a normal extending in the vertical direction at an intersection point where the discharge axis intersects the upper surface 91 of the substrate 9 and the discharge axis is 60 degrees, and in other words, an angle formed by the perspective discharge axis and the discharge axis is 30 degrees.

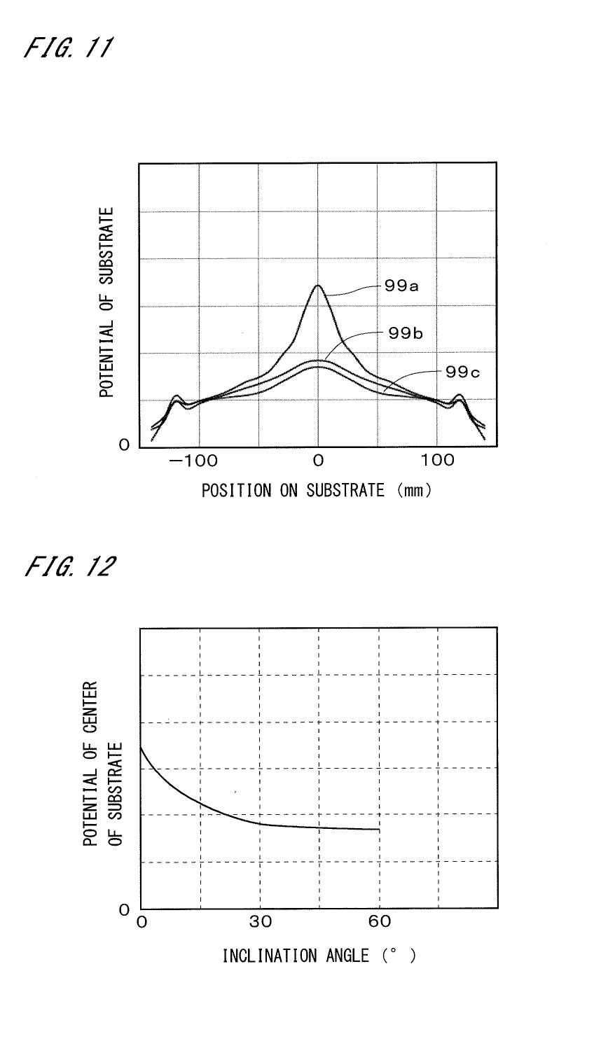

FIG. 12 is a graph showing a relation between the inclination angle and the potential at the center of the substrate 9 shown in FIG. 11. In FIG. 12, the horizontal axis represents an inclination angle and the vertical axis represents a potential at the center of the substrate 9. As shown in FIGS. 11 and 12, by setting the inclination angle to be larger than or equal to 30 degrees, it is possible to significantly reduce the potential at the center of the substrate 9. In the substrate processing apparatus 1, it is preferable that an angle formed by the discharge direction of the deionized water from at least one discharge port 188 among the plurality of discharge ports 188 and the central axis J1 should be larger than or equal to 30 degrees. It is thereby possible to suppress the electrification at the center portion of the substrate 9.

The substrate processing apparatus 1 allows various variations.

For example, in the upper nozzles 181 and 181b, around the central discharge port 188a, four or more peripheral discharge ports 188b may be disposed at regular angular intervals on the same circumference. The plurality of peripheral discharge ports 188b do not necessarily need to be disposed on the same circumference. The plurality of peripheral discharge ports 188b do not necessarily need to be disposed at regular angular intervals. The plurality of peripheral discharge ports 188b may be disposed around the central discharge port 188a in various arrangements. Only one peripheral discharge port 188b may be provided around the central discharge port 188a.

Further, in the upper nozzles 181 and 181b, it is not always necessary to provide the central discharge port 188a, but the plurality of discharge ports 188 may be arranged in an appropriate distribution in the bottom surface 181a of the upper nozzle 181 or 181b. In such a case, it is preferable that the plurality of discharge ports 188 should be disposed in an almost uniform distribution.

The upper nozzles 181 and 181b do not necessarily need to be so fixed as to face the center portion of the upper surface 91 of the substrate 9. The upper nozzles 181 and 181b may have, for example, a structure to supply a processing liquid (the above-described chemical liquid, deionized water, IPA, or the like) while repeating a reciprocating motion between the center portion of the substrate 9 and the outer edge portion thereof above the substrate 9, only if the upper nozzles 181 and 181b can supply the processing liquid onto at least the center portion of the upper surface 91.

In the substrate processing apparatus 1, the deionized water from the upper nozzle 181 or 181b does not necessarily need to be continuously discharged like a liquid column, but fine droplets of deionized water, for example, may be discharged toward the substrate 9 from each discharge port 188 of the upper nozzle 181 or 181b. The same applies to other processing liquids (the above-described chemical liquid and IPA).

In the substrate processing apparatus 1, a pressurizing part for supplying gas into the chamber space 120 to pressurize the chamber space 120 may be provided.

The chamber space 120 is pressurized in the second sealed state in which the chamber 12 is sealed and brought into a pressurized atmosphere where the pressure of the chamber 12 is higher than the atmosphere pressure. Further, the heating gas supply part 187 may also serve as the pressurizing part.

The chamber opening and closing mechanism 131 does not necessarily need to move the chamber cover 122 in the vertical direction, but may move the chamber body 121 in the vertical direction with the chamber cover 122 fixed. The chamber 12 does not necessarily need to have a substantially cylindrical shape but may have any of various shapes.

The shapes and structures of the stator part 151 and the rotor part 152 in the substrate rotating mechanism 15 may be changed in various manners. The rotor part 152 does not necessarily need to be rotated, being in a floating state. There may be another case where a structure such as a guide or the like for mechanically supporting the rotor part 152 in the chamber 12 is provided and the rotor part 152 is rotated along the guide. The substrate rotating mechanism 15 does not necessarily need to be a hollow motor, but an axis rotation type motor may be used as the substrate rotating mechanism.

In the substrate processing apparatus 1, the cleaning process of the substrate may be performed in the enlarged sealed space 100 in the first sealed state. The enlarged sealed space 100 may be formed by bring any portion (e.g., the sidewall 611) other than the upper surface part 612 of the cup part 161 into contact with the chamber cover 122. The shape of the cup part 161 may be changed as appropriate. The cleaning process of the substrate 9 does not necessarily need to be performed in the sealed state but may be performed in the open state.

The shapes of the upper nozzle 181, the lower nozzle 182, and the heating gas supply nozzle 180a are not limited to a protruding shape. Any portion having a discharge port for discharging the processing liquid or an ejection port for ejecting the inert gas or the heating gas may be included in a concept of the nozzle in the preferred embodiment of the present invention.

In the substrate processing apparatus 1, various processings, other than the above-described etching, such as removal of an oxide film on the substrate, development using a developing solution, or the like, may be performed by using the chemical liquid supplied from the chemical liquid supply part 183.

The substrate processing apparatus 1 may be used for processing a glass substrate used in a display device such as a liquid crystal display, a plasma display, FED (Field Emission Display), and the like, other than the semiconductor substrate. Alternatively, the substrate processing apparatus 1 may be used for processing a substrate for optical disk, a substrate for magnetic disk, a substrate for magneto-optic disk, a substrate for photomask, a ceramic substrate, a substrate for solar battery, and the like.

The configurations of the above-described preferred embodiment and variations may be appropriately combined as long as there are no mutual inconsistencies.

While the invention has been shown and described in detail, the foregoing description is in all aspects illustrative and not restrictive. It is therefore understood that numerous modifications and variations can be devised without departing from the scope of the invention. This application claims priority benefit under 35 U.S.C. Section 119 of Japanese Patent Application No. 2013-069990 filed in the Japan Patent Office on Mar. 28, 2013, the entire disclosure of which is incorporated herein by reference.

### REFERENCE SIGNS LIST

1 Substrate processing apparatus

9 Substrate

12 Chamber

15 Substrate rotating mechanism

91 Upper surface (of Substrate)

120 Chamber space

121 Chamber body

122 Chamber cover

141 Substrate supporting part

181, 181b Upper nozzle

188 Discharge port

188a Central discharge port

188b Peripheral discharge port

J1 Central axis

S11 to S16 Step

1. A substrate processing apparatus for processing a substrate, comprising:
a substrate supporting part for supporting a substrate in a horizontal state;
a nozzle for discharging deionized water as a cleaning solution toward a center portion of an upper surface of said substrate from a plurality of discharge ports; and
a substrate rotating mechanism for rotating said substrate supporting part together with said substrate around a central axis directed in a vertical direction.

2. The substrate processing apparatus according to claim 1, wherein
said plurality of discharge ports include:
a central discharge port disposed at a center; and
a plurality of peripheral discharge ports disposed at regular angular intervals on a circumference around said central axis.

3. The substrate processing apparatus according to claim 1, wherein
said plurality of discharge ports are disposed within a circle having a radius smaller than or equal to 60 mm around said central axis.

4. The substrate processing apparatus according to claim 1, wherein
said plurality of discharge ports are disposed within a circle having a radius smaller than or equal to 40% of a radius of said substrate around said central axis.

5. The substrate processing apparatus according to claim 1, wherein
a flow rate of said cleaning solution discharged from each of said plurality of discharge ports is lower than or equal to 1 liter per minute.

6. The substrate processing apparatus according to claim 5, wherein
said cleaning solution is continuously discharged like a liquid column from each of said plurality of discharge ports.

7. The substrate processing apparatus according to claim 1, wherein
an angle formed by a discharge direction of said cleaning solution from at least one discharge port among said plurality of discharge ports and said central axis is larger than or equal to 30 degrees.

8. The substrate processing apparatus according to claim 7, wherein
said cleaning solution is continuously discharged like a liquid column from each of said plurality of discharge ports.

9. The substrate processing apparatus according to claim 1, further comprising:
a sealed space forming part forming an internal space which is sealed, in which a cleaning process is performed on said substrate by using said cleaning solution.

10. The substrate processing apparatus according to claim 1, wherein
said cleaning solution is continuously discharged like a liquid column from each of said plurality of discharge ports.

11. A substrate processing method of processing a substrate, comprising:
a) rotating a substrate in a horizontal state around a central axis directed in a vertical direction; and
b) discharging deionized water as a cleaning solution toward a center portion of an upper surface of the substrate from a plurality of discharge ports.

12. The substrate processing method according to claim 11, wherein said plurality of discharge ports include:
a central discharge port disposed on said center axis; and
a plurality of peripheral discharge ports disposed at regular angular intervals on a circumference around said central axis.

13. The substrate processing method according to claim 11, wherein
said plurality of discharge ports are disposed within a circle having a radius smaller than or equal to 60 mm around said central axis.

14. The substrate processing method according to claim 11, wherein
said plurality of discharge ports are disposed within a circle having a radius smaller than or equal to 40% of a radius of said substrate around said central axis.

15. The substrate processing method according to claim 11, wherein
in said operation b), a flow rate of said cleaning solution discharged from each of said plurality of discharge ports is lower than or equal to 1 liter per minute.

16. The substrate processing method according to claim 15, wherein
in said operation b), said cleaning solution is continuously discharged like a liquid column from each of said plurality of discharge ports.

17. The substrate processing method according to claim 11, wherein
in said operation b), an angle formed by a discharge direction of said cleaning solution from at least one discharge port among said plurality of discharge ports and said central axis is larger than or equal to 30 degrees.

18. The substrate processing method according to claim 17, wherein
in said operation b), said cleaning solution is continuously discharged like a liquid column from each of said plurality of discharge ports.

19. The substrate processing method according to claim 11, wherein
said operation b) is performed in a space which is sealed.

20. The substrate processing method according to claim 11, wherein
in said operation b), said cleaning solution is continuously discharged like a liquid column from each of said plurality of discharge ports.
